(19) United States
(12) Patent Application Publication
(10) Pub. No.: US 2024/0162061 A1
(43) Pub. Date: May 16, 2024

(54) SUBSTRATE PROCESSING APPARATUS, SUBSTRATE PROCESSING SYSTEM, AND SUBSTRATE PROCESSING METHOD

(71) Applicant: Tokyo Electron Limited, Tokyo (JP)

(72) Inventors: Yoshihiro KAWAGUCHI, Kikuchi-gun, Kumamoto (JP); Yohei YAMASHITA, Kikuchi-gun, Kumamoto (JP)

(21) Appl. No.: 18/549,934

(22) PCT Filed: Feb. 28, 2022
(86) PCT No.: PCT/JP2022/008206

§ 371 Date: Sep. 11, 2023

(30) Foreign Application Priority Data
Mar. 12, 2021 (JP) 2021-040497

(51) Int. Cl. H01L 21/67; H01L 21/268

(52) U.S. Cl. CPC H01L 21/67092; H01L 21/268

(57) ABSTRACT

A substrate processing apparatus configured to process a substrate by radiating laser light to the substrate includes a substrate holder configured to hold the substrate; a laser radiation lens configured to radiate the laser light to the substrate held by the substrate holder; a laser oscillator configured to emit the laser light toward a space above a substrate holding surface of the substrate holder; a mirror configured to change, above the substrate holder, a direction of the laser light emitted from the laser oscillator into a horizontal direction; and an optical system configured to adjust an output of the laser light incident from the mirror, and guide the laser light to the laser radiation lens.

### TECHNICAL FIELD

The various aspects and embodiments described herein pertain generally to a substrate processing apparatus, a substrate processing system, and a substrate processing method.

### BACKGROUND

Patent Document 1 discloses a laser processing apparatus in which a processing mechanism configured to perform a laser processing on a wafer is disposed at an upper side and a holding table configured to hold the wafer is disposed at a lower side. The processing mechanism has a processing head configured to radiate a laser light to the wafer and an oscillator configured to oscillate the laser light. The oscillator is provided in a housing which is disposed above the processing head.

### PRIOR ART DOCUMENT

Patent Document 1: Japanese Patent Laid-open Publication No. 2011-187481

### DISCLOSURE OF THE INVENTION

### Problems to be Solved by the Invention

Exemplary embodiments provide a technique enabling downsizing of a substrate processing apparatus configured to process a substrate by irradiating laser light to the substrate.

### Means for Solving the Problems

In an exemplary embodiment, a substrate processing apparatus configured to process a substrate by radiating laser light to the substrate includes a substrate holder configured to hold the substrate; a laser radiation lens configured to radiate the laser light to the substrate held by the substrate holder; a laser oscillator configured to emit the laser light toward a space above a substrate holding surface of the substrate holder; a mirror configured to change, above the substrate holder, a direction of the laser light emitted from the laser oscillator into a horizontal direction; and an optical system configured to adjust an output of the laser light incident from the mirror, and guide the laser light to the laser radiation lens.

### Effect of the Invention

According to the exemplary embodiments, it is possible to downsize the substrate processing apparatus configured to process the substrate by radiating the laser light to the substrate.

### BRIEF DESCRIPTION OF THE DRAWINGS

FIG. 1 is a side view illustrating a configuration of a combined wafer to be processed in a wafer processing system.

FIG. 2 is a plan view schematically illustrating a configuration of a wafer processing system according to an exemplary embodiment.

FIG. 3A and FIG. 3B are explanatory diagrams illustrating a state in which a first wafer is being separated from a laser absorbing layer.

FIG. 4 is a side view schematically illustrating a configuration of a wafer processing apparatus according to the exemplary embodiment.

FIG. 5 is a side view schematically illustrating the configuration of the wafer processing apparatus according to the exemplary embodiment.

FIG. 6 is a side view schematically illustrating the configuration of the wafer processing apparatus according to the exemplary embodiment.

FIG. 7 is a side view illustrating an arrangement of the wafer processing apparatus and a wafer transfer device according to the exemplary embodiment.

FIG. 8 is a side view illustrating a schematic configuration of a wafer processing apparatus according to another exemplary embodiment.

FIG. 9 is a side view illustrating the schematic configuration of the wafer processing apparatus according to the another exemplary embodiment.

FIG. 10 is a side view illustrating a schematic configuration of a wafer processing apparatus according to still another exemplary embodiment.

### DETAILED DESCRIPTION

In a manufacturing process for a semiconductor device, a semiconductor wafer (hereinafter, simply referred to as “wafer”) is processed by being radiated with laser light. This laser processing is performed for various purposes, such as when performing so-called laser lift-off in which a device layer formed on a surface of one wafer is transferred to another wafer, or when separating a wafer.

In recent years, in order to perform the laser processing efficiently, an output of the laser light is getting higher, and, along with this, a laser oscillator configured to oscillate the laser light is getting larger in size. Conventionally, in the laser processing apparatus disclosed in Patent Document 1, for example, the laser oscillator is provided so as to extend in a horizontal direction. For this reason, as the size of the laser oscillator increases, the laser processing apparatus is scaled up in the horizontal direction, resulting in an increase of the occupied area (footprint) of the laser processing apparatus. In such a case, since the number of laser processing apparatuses that can be provided in a wafer processing space is reduced, the number of wafers processed (the number of wafers produced) is also reduced.

Further, in the laser processing apparatus disclosed in Patent Document 1, the holding table configured to hold the wafer, the processing head configured to radiate the laser light to the wafer, and the laser oscillator configured to oscillate the laser light are arranged in this order from the bottom. As a result, the laser processing apparatus becomes larger in a height direction, so that a height position of the laser oscillator located at the upper side becomes high. In such a case, when maintaining the laser oscillator, for example, the laser oscillator, which is a heavy object, needs to be separated from a high place and installed thereat, which makes the maintenance take time and effort.

The present disclosure pertains to a technique of downsizing a substrate processing apparatus configured to process a substrate by radiating laser light to the substrate. Hereinafter, a wafer processing apparatus as a substrate processing apparatus, a wafer processing system as a substrate processing system, and a wafer processing method as a substrate processing method according to an exemplary embodiment will be described with reference to the accompanying drawings. Further, in the present specification and the drawings, parts having substantially the same functions and configurations will be assigned same reference numerals, and redundant description will be omitted.

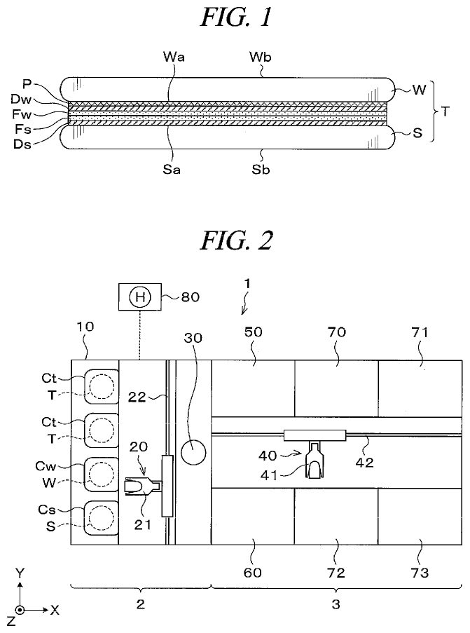

In a wafer processing system 1 to be described later according to the present exemplary embodiment, a processing is performed on a combined wafer T as a substrate in which a first wafer W and a second wafer S are bonded to each other as shown in FIG. 1. Below, in the first wafer W, a surface to be bonded to the second wafer S will be referred to as a front surface Wa, and a surface opposite to the front surface Wa will be referred to as a rear surface Wb. Likewise, in the second wafer S, a surface to be bonded to the first wafer W will be referred to as a front surface Sa, and a surface opposite to the front surface Sa will be referred to as a rear surface Sb.

The first wafer W is a semiconductor wafer such as, but not limited to, a silicon substrate. A laser absorbing layer P, a device layer Dw, and a surface film Fw are stacked on the front surface Wa of the first wafer W in this order from the front surface Wa side. The laser absorbing layer P is configured to absorb laser light radiated from a laser radiation mechanism 110 as will be described later. For example, an oxide film (SiO₂ film) may be used as the laser absorbing layer P. However, the laser absorbing layer P is not particularly limited as long as it is capable of absorbing the laser light. The device layer Dw includes a plurality of devices. The surface film Fw may be, by way of non-limiting example, an oxide film (a SiO₂ film or a TEOS film), a SiC film, a SiCN film, an adhesive, or the like. Further, the position of the laser absorbing layer P is not limited to that shown in the above-described exemplary embodiment, and the laser absorbing layer P may be formed between the device layer Dw and the surface film Fw, for example. Furthermore, the device layer Dw and the surface film Fw may not be formed on the front surface Wa. In this case, the laser absorbing layer P is formed on the second wafer S, and a device layer Ds of the second wafer S is transferred to the first wafer W.

The second wafer S is also a semiconductor wafer such as, but not limited to, a silicon substrate. The device layer Ds and a surface film Fs are stacked on the front surface Sa of the second wafer S in this order from the front surface Sa side. The device layer Ds and the surface film Fs are the same as the device layer Dw and the surface film Fw of the first wafer W, respectively. Furthermore, the device layer Ds and the surface film Fs may not be formed on the front surface Sa. The surface film Fw of the first wafer W and the surface film Fs of the second wafer S are bonded.

As depicted in FIG. 2, the wafer processing system 1 includes a carry-in/out station 2 and a processing station 3 that are connected as one body. In the carry-in/out station 2, cassettes Ct, Cw, and Cs capable of accommodating therein a plurality of combined wafers T, a plurality of first wafers W, and a plurality of second wafers S, respectively, are carried to/from, for example, the outside. The processing station 3 is equipped with various processing apparatuses each configured to perform a required processing on the combined wafer T.

In the carry-in/out station 2, a cassette placing table 10 is disposed. In the shown example, the multiple cassettes Ct, Cw, and Cs can be arranged on the cassette placing table 10 in a row in the Y-axis direction. Here, the number of the cassettes Ct, Cw, and Cs disposed on the cassette placing table 10 may be selected as required.

In the carry-in/out station 2, a wafer transfer device 20 is provided adjacent to the cassette placing table 10 on the positive X-axis side of the cassette placing table 10. The wafer transfer device 20 has a transfer arm 21 configured to hold and transfer the combined wafer T, the first wafer W, and the second wafer S. Further, the wafer transfer device 20 is configured to move on a transfer path 22 extending in the Y-axis direction to transfer the combined wafer T, the first wafer W, and the second wafer S between the cassettes Ct, Cw, and Cs of the cassette placing table 10 and a transition device 30 to be described later.

In the carry-in/out station 2, the transition device 30 configured to deliver the combined wafer T, the first wafer W, and the second wafer S to/from the processing station 3 is provided adjacent to the wafer transfer device 20 on the positive X-axis side of the wafer transfer device 20.

The processing station 3 is provided with a wafer transfer device 40 as a substrate transfer device, a cleaning apparatus 50, a separating apparatus 60, and wafer processing apparatuses 70 to 73. The wafer transfer device 40 is disposed on the positive X-axis side of the transition device 30. On the positive Y-axis side of the wafer transfer device 40, the cleaning apparatus 50 and the two wafer processing apparatuses 70 and 71 are arranged side by side from the negative X-axis side toward the positive X-axis side. On the negative Y-axis side of the wafer transfer device 40, the separation apparatus 60 and the two wafer processing apparatuses 72 and 73 are arranged side by side from the negative X-axis side toward the positive X-axis side.

The wafer transfer device 40 has a transfer arm 41 configured to hold and transfer the combined wafer T, the first wafer W, and the second wafer S. The wafer transfer device 40 is configured to move on a transfer path 42 extending in the X-axis direction to transfer the combined wafer T to the transition device 30 of the carry-in/out station 2, the cleaning apparatus 50, the separating apparatus 60, and the wafer processing apparatuses 70 to 73.

The cleaning apparatus 50 is configured to clean a surface of the laser absorbing layer P formed on the front surface Sa of the second wafer S separated by the separating apparatus 60. In addition, the cleaning apparatus 50 may be configured to clean the rear surface Sb of the second wafer S as well as the front surface Sa thereof.

The separating apparatus 60 is configured to separate the first wafer W from the second wafer S in the combined wafer T after being subjected to a laser processing by the wafer processing apparatuses 70 to 73.

The wafer processing apparatuses 70 to 73 are configured to radiate laser light to the laser absorbing layer P of the first wafer W to cause separation at an interface between the laser absorbing layer P and the first wafer W. The configuration of the wafer processing apparatuses 70 to 73 will be described later.

The above-described wafer processing system 1 has a controller 80. The controller 80 is, for example, a computer equipped with a CPU, a memory, and the like, and has a program storage (not shown). The program storage stores therein a program for controlling a processing of the combined wafer T in the wafer processing system 1. The program may be recorded in a computer-readable recording medium H and installed from the recording medium H to the controller 80. Further, the recording medium H may be transitory or non-transitory.

Now, a wafer processing performed by using the wafer processing system 1 configured as described above will be discussed. In the present exemplary embodiment, the first wafer W and the second wafer S are bonded to each other in a bonding apparatus (not shown) outside the wafer processing system 1 to form the combined wafer T in advance.

First, the cassette Ct accommodating therein the plurality of combined wafers T is placed on the cassette placing table 11 of the carry-in/out station 2.

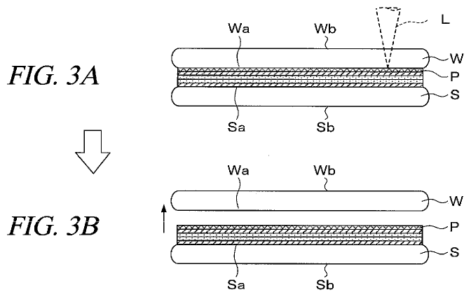

Subsequently, the combined wafer T in the cassette Ct is taken out by the wafer transfer device 20 and transferred to the transition device 30, and then transferred to the wafer processing apparatus 70 by the wafer transfer device 40. In the wafer processing apparatus 70, as shown in FIG. 3A, the laser absorbing layer P of the first wafer W, more specifically, the interface between the laser absorbing layer P and the first wafer W is radiated with laser light L (CO₂ laser light) in a pulse shape. The laser light L is radiated to the entire surface of the laser absorbing layer P. Further, the laser light L penetrates the first wafer W from the rear surface Wb side of the first wafer W, and is absorbed by the laser absorbing layer P. Due to this laser light L, the separation occurs at the interface between the laser absorbing layer P and the first wafer W.

Thereafter, the combined wafer T is transferred to the separating apparatus 60 by the wafer transfer device 40. In the separating apparatus 60, in the state that the rear surface Wb of the first wafer W is attracted to and held by an attraction pad (not shown), the attraction pad is raised, so that the laser absorbing layer P is separated from the first wafer W, as shown in FIG. 3B.

The separated first wafer W is transferred to the transition device 30 by the wafer transfer device 40, and then transferred to the cassette Cw on the cassette placing table 11 by the wafer transfer device 20. Further, the first wafer W carried out from the separating apparatus 60 may be transferred to the cleaning apparatus 50 before being carried into the cassette Cw, so that the front surface Wa, which is a separation surface, may be cleaned.

Meanwhile, the separated second wafer S is transferred to the cleaning apparatus 50 by the wafer transfer device 40. In the cleaning apparatus 50, the surface of the laser absorbing layer P, which is a separation surface, is cleaned. Further, in the cleaning apparatus 50, the rear surface Sb of the second wafer S may be cleaned together with the surface of the laser absorbing layer P. In addition, cleaning devices configured to clean the surface of the laser absorbing layer P and the rear surface Sb of the second wafer S may be provided individually.

Thereafter, the second wafer S after being subjected to all the required processings is transferred to the transition device 30 by the wafer transfer device 40, and then transferred to the cassette Cs on the cassette placing table 11 by the wafer transfer device 20. In this way, the series of processes of the wafer processing in the wafer processing system 1 are completed.

Now, the aforementioned wafer processing apparatuses 70 to 73 will be described.

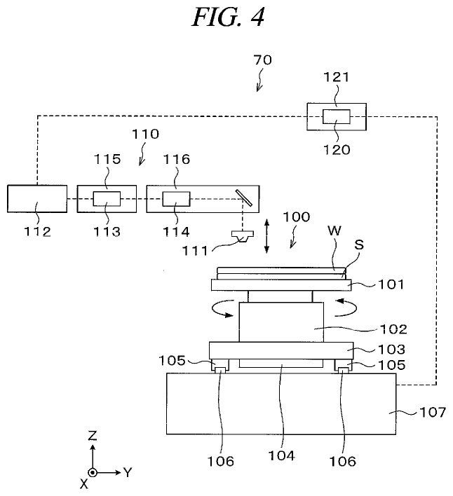

As illustrated in FIG. 4, the wafer processing apparatus 70 includes a stage 100, the laser radiation mechanism 110, and an electric equipment 120. The stage 100 is configured to hold the combined wafer T to process it. The laser radiation mechanism 110 is configured to radiate laser light to the combined wafer T held by the stage 100.

The stage 100 has a chuck 101 as a substrate holder, an air bearing 102, a slider table 103, a rotation mechanism 104, a moving mechanism 105, a rail 106, and a base 107. The chuck 101 holds the combined wafer T on a top surface thereof, while attracting and holding the rear surface Sb of the second wafer S.

The chuck 101 is supported by the slider table 103 with the air bearing 102 therebetween. The rotation mechanism 104 is provided on a bottom surface of the slider table 103. The rotation mechanism 104 incorporates therein, for example, a motor as a driving source. The chuck 101 is configured to be rotatable around a θ-axis (vertical axis) by the rotation mechanism 104 via the air bearing 102. The slider table 103 is configured to be movable along the rail 106 extending in the X-axis direction by the moving mechanism 105 provided on a bottom surface thereof. The rail 106 is provided on the base 107. Further, although the driving source of the moving mechanism 105 is not particularly limited, a linear motor is used, for example.

The laser radiation mechanism 110 has a laser radiation lens 111, a laser oscillator 112, a mirror 113, and an optical system 114.

The laser radiation lens 111 is disposed above the chuck 101. The laser radiation lens 111 is, for example, a cylindrical member, and radiates laser light to the combined wafer T held by the chuck 101. The laser light emitted from the laser radiation lens 111 penetrates the first wafer W and is radiated to the laser absorbing layer P. Further, the laser radiation lens 111 may be configured to be movable up and down by an elevation mechanism (not shown).

The laser oscillator 112 is configured to oscillate and emit the laser light in a pulse shape. That is, this laser light is a so-called pulse laser. In the present exemplary embodiment, the laser light is CO₂ laser light, and the CO₂ laser light has a wavelength of, e.g., 8.9 μm to 11 μm.

The mirror 113 is configured to change the direction of the laser light emitted from the laser oscillator 112 into a direction of the optical system 114, that is, into a horizontal direction as will be described later. For example, when the laser oscillator 112 is replaced or due to a device difference of the laser oscillator 112, the emission position or the emission direction of the laser light from the laser oscillator 112 may be changed. Even in this case, the direction of the laser light can be corrected by the mirror 113 without needing to change the optical system 114. The mirror 113 is accommodated in a mirror box 115.

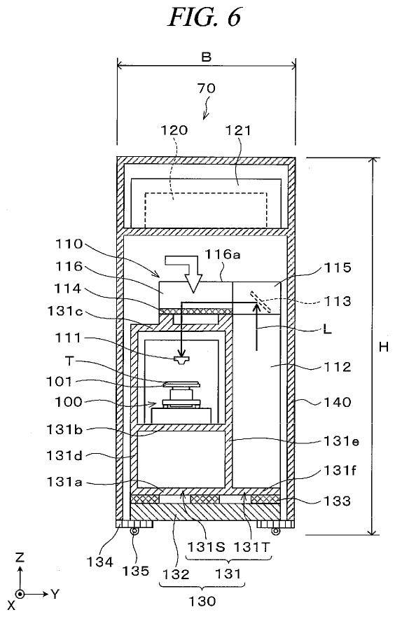

The optical system 114 is configured to adjust an output of the laser light incident from the mirror 113, and guide this laser light to the laser radiation lens 111. The optical system 114 is accommodated in an optical system box 116. The optical system 114 is composed of, for example, a plurality of mirrors, a beam expander, DOE (Diffractive Optical Elements), and the like. As shown in FIG. 6, these components of the optical system 114 are arranged horizontally on a bottom surface inside the optical system box 116. The laser light incident from the mirror 113 is emitted downwards through the optical system 114 to be guided to the laser radiation lens 111. A top plate 116a of the optical system box 116 is configured in a detachable manner. With the top plate 116a separated, the inside of the optical system box 116 is accessible from a horizontal direction and from above (as indicated by a block arrow in FIG. 6), and maintenance of the optical system 114, for example, may be performed.

The electric equipment 120 is used in each component of the wafer processing apparatus 70, and includes an electric equipment for use in the stage 100 or the laser radiation mechanism 110. The electric equipment 120 is accommodated in an electric equipment box 121.

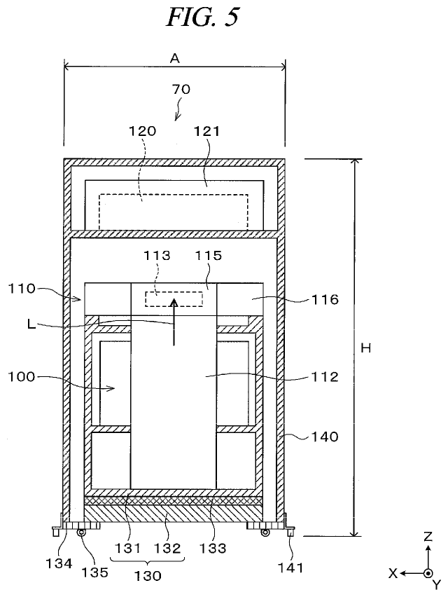

As shown in FIG. 5 to FIG. 8, the wafer processing apparatus 70 further includes a support frame 130 and a connection frame 140. The support frame 130 supports at least the stage 100 and the laser oscillator 112. The connection frame 140 is provided outside the support frame 130 so as to surround the support frame 130.

The support frame 130 includes an upper support frame 131 and a lower support frame 132. An insulator 133 is provided between the upper support frame 131 and the lower support frame 132. By way of non-limiting example, an anti-vibration rubber is used as the insulator 133. This insulator 133 suppresses vibration of the lower support frame 132 from being transmitted to the upper support frame 131.

The upper support frame 131 is partitioned into a first support region 131S on the negative Y-axis side where the stage 100 is placed, and a second support region 131T on the positive Y-axis positive side where the laser oscillator 112 is placed. The first support region 131S is a region composed of beams 131a, 131b, and 131c and columns 131d and 131e. The beams 131a, 131b, and 131c are arranged in three levels in this order from the bottom. The columns 131d and 131e are arranged in this order from the negative Y-axis side toward the positive Y-axis side. The second support region 131T is a region composed of a beam 131f and a column 131e. The beam 131f may be the same as the beam 131a, or may be connected to the beam 131a.

In the first support region 131S, the stage 100 is supported on the beam 131b at the middle level, and the optical system box 116 is supported on the beam 131c at the upper level. That is, the optical system box 116 is disposed above the stage 100.

In the second support region 131T, the laser oscillator 112 is supported on the beam 131f. Alternatively, the laser oscillator 112 may be supported by the column 131e. The laser oscillator 112 is disposed to extend in a height direction. Further, under the laser oscillator 112, an electric cable, a cooling water supply pipe, and the like are connected, and a space for accommodating them is secured. The mirror box 115 is stacked on top of the laser oscillator 112.

The stage 100 and the laser oscillator 112 are arranged in a horizontal direction. At least a part of the stage 100 and a part of the laser oscillator 112 have the same height, that is, the stage 100 and the laser oscillator 112 overlap in the height direction when viewed from the side. Also, the optical system box 116 and the mirror box 115 are arranged in the horizontal direction, and, in the present exemplary embodiment, a top surface of the optical system box 116 and a top surface of the mirror box 115 have the same height.

The components of the laser radiation mechanism 110 are arranged as described above. In this case, as indicated by arrows in FIG. 5 and FIG. 6, the laser light L is emitted from the laser oscillator 112 toward a space above a wafer holding surface of the chuck 101 of the stage 100. The laser light L from the laser oscillator 112 is incident on the mirror box 115 above the stage 100, and the direction of the laser light L is changed into the horizontal direction (negative Y-axis direction) by the mirror 113. The laser light L from the mirror box 115 is incident on the optical system box 116, and after the output of the laser light L is adjusted by the optical system 114, the laser light L is guided to the laser radiation lens 111 provided below. Then, the laser light L is radiated from the laser radiation lens 111 to the combined wafer T held by the chuck 101.

A connection member 134 is provided at each of four corners of a lower end of the lower support frame 132 and is connected to a lower end of the connection frame 140. A caster 135 is provided on a bottom surface of the connection member 134, and the support frame 130 and the component supported by the support frame 130 are configured to be movable independently.

The electric equipment box 121 is supported by the connection frame 140. The electric equipment box 121 is supported at the uppermost end of the connection frame 140, that is, the electric equipment box 121 is disposed above the laser radiation mechanism 110 and the stage 100 supported by the upper support frame 131.

The connection member 134 is connected to each of the four corners of the lower end of the connection frame 140 as described above. Further, a caster 141 is provided at a lower end of the connection frame 140, and the connection frame 140 and the components supported by the connection frame 140 are configured to be movable independently.

The connection frame 140 of the wafer processing apparatus 70 is connected to frames of adjacent apparatuses. That is, the connection frame 140 is connected to a connection frame 140 of the wafer processing apparatus 71, a frame (not shown) of the cleaning apparatus 50, and a frame 150 of a wafer transfer region accommodating therein the wafer transfer device 40.

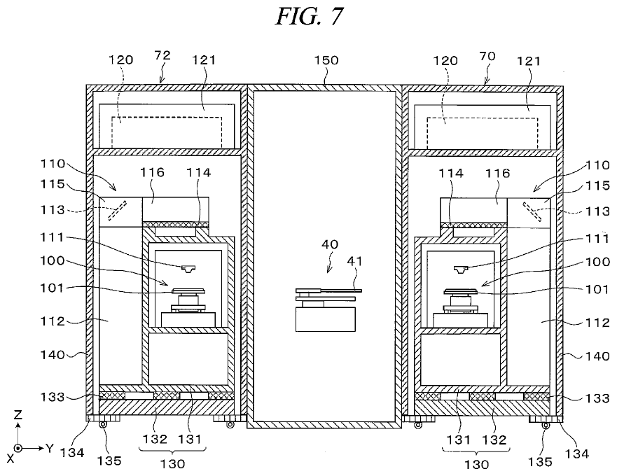

In addition, the other wafer processing apparatuses 71 to 73 have the same configuration as the wafer processing apparatus 70 described above. However, in the wafer processing apparatuses 70 and 71 and the wafer processing apparatuses 72 and 73, the direction in the Y-axis direction is different. As shown in FIG. 7, the wafer processing apparatus 70 and the wafer processing apparatus 72 are disposed to face each other with the wafer transfer device 40 therebetween. In this case, a laser oscillator 112 and a stage 100 of the wafer processing apparatus 72, the wafer transfer device 40, and the stage 100 and the laser oscillator 112 of the wafer processing apparatus 70 are arranged in this order from the positive Y-axis side toward the negative Y-axis side. Also, the arrangement of the wafer processing apparatus 71 and the wafer processing apparatus 73 is the same as the arrangement of the wafer processing apparatus 70 and the wafer processing apparatus 72.

In the wafer processing apparatus 70 according to the above-described exemplary embodiment, the laser oscillator 112 extends in the height direction and is configured to emit the laser light upwards. Thus, even if the laser oscillator 112 is enlarged in size, the wafer processing apparatus 70 can be downsized. Hereinafter, effects of the present exemplary embodiment will be described in comparison with a conventional wafer processing apparatus. In the conventional wafer processing apparatus, a laser oscillator is disposed to extend in a horizontal direction.

In the conventional wafer processing apparatus, the laser oscillator is provided above a stage. The laser oscillator extends in a horizontal direction (in the X-axis direction in the present exemplary embodiment). The laser oscillator, a laser optical system, and a controller of a driving unit are arranged side by side in the X-axis direction. In this case, if the laser oscillator is scaled up, the width of the laser oscillator in the X-axis direction increases, resulting in an increase of the width of the wafer processing apparatus in the X-axis direction. Further, if the laser oscillator, a laser optical system box, and a controller including an electric equipment are stacked on top of each other in order to reduce the width of the wafer processing apparatus in the X-axis direction, the height of the wafer processing apparatus also increases.

As described above, since the width of the conventional wafer processing apparatus in the X-axis direction in the present exemplary embodiment is large, the area occupied by the wafer processing apparatus is increased. In this case, if this conventional wafer processing apparatus is installed in the wafer processing system 1 according to the present exemplary embodiment, the total number of wafer processing apparatuses may be reduced due to the limitation in the width in the X-axis direction in an installation place. As a result, the number of wafers processed is also reduced.

In addition, as the height of the conventional wafer processing apparatus increases, a height position where the laser oscillator is installed becomes higher. In such a case, when performing the maintenance of the laser oscillator, for example, since the laser oscillator, which is the heavy object, needs to be separated and installed at the high place, a large jig (lifter) or crane, for example, is required. As a result, the maintenance of the laser oscillator takes time and effort.

In addition, since the height of the conventional wafer processing apparatus increases, it becomes difficult to access the optical system box including the laser optical system from above.

In the wafer processing apparatus 70 according to the present exemplary embodiment, however, the laser oscillator 112 is disposed to extend in the height direction, as illustrated in FIG. 5 and FIG. 6. For this reason, even if the laser oscillator 112 is enlarged, the width A of the wafer processing apparatus 70 in the X-axis direction can be made smaller than that of the conventional wafer processing apparatus, so that the area occupied by the wafer processing apparatus 70 can be reduced. Further, the length B of the wafer processing apparatus 70 in the Y-axis direction is equal to or less than that of the conventional wafer processing apparatus. In such a case, the number of wafer processing apparatuses 70 that can be installed in the wafer processing system 1 of the present exemplary embodiment increases. For example, four wafer processing apparatuses 70 may be installed. As a result, the number of combined wafers T processed can be increased.

Moreover, since the height H of the wafer processing apparatus 70 is also smaller than that of the conventional wafer processing apparatus, the height position of the laser oscillator 112 can be lowered. Specifically, for example, an operator may directly access the laser oscillator 112. In particular, since the laser oscillator 112 is disposed on the opposite side to the wafer transfer device 40, an operator can easily access the laser oscillator 112. As a result, the maintenance of the laser oscillator 112 can be performed without any trouble in a short time, so that efficiency of the maintenance can be improved.

In addition, since the height H of the wafer processing apparatus 70 decreases, the optical system box 116 can be accessed from the horizontal direction and from above (as indicated by the block arrow in FIG. 6) with the top plate 116a separated. Thus, accessibility may be improved. As a result, the efficiency of the maintenance of the optical system 114 of the optical system box 116 can be improved.

Also, in the present exemplary embodiment, the connection frame 140 of the wafer processing apparatus 70 is connected to the frame 150 of the wafer transfer region. In this case, even if vibration occurs when the wafer transfer device 40 is driven, for example, the vibration is transmitted to the connection frame 140 of the wafer processing apparatus 70 via the frame 150 of the wafer transfer region. Here, since the connection frame 140 is connected to the support frame 130 only by the connection member 134, transmission of the vibration of the connection frame 140 to the support frame 130 can be suppressed.

In addition, even if floor vibration is transmitted to the lower support frame 132 of the support frame 130, this vibration can be suppressed from being transmitted to the upper support frame 131 as the insulator 133 is provided between the lower support frame 132 and the upper support frame 131.

Further, the stage 100 and the laser radiation mechanism 110 are supported by the upper support frame 131. In this case, even when the upper support frame 131 vibrates, for example, an amplitude error or a phase error between the combined wafer T held by the chuck 101 of the stage 100 and the laser radiation lens 111 (processing point) can be suppressed. Therefore, when the laser light is radiated from the laser radiation lens 111 to the laser absorbing layer P of the combined wafer T, the laser light can be suppressed from being radiated in a zigzag shape, and a positional deviation of the laser light can be suppressed. As a result, the laser processing on the combined wafer T can be appropriately performed with high precision.

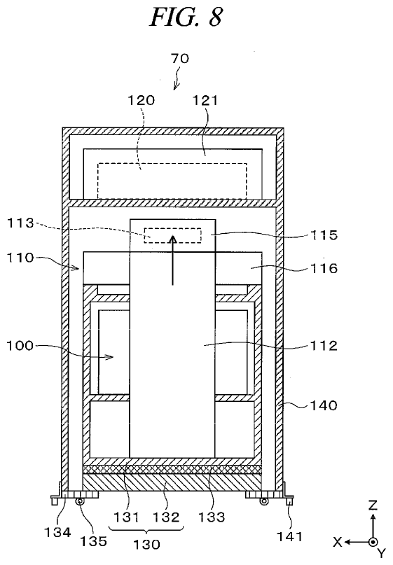

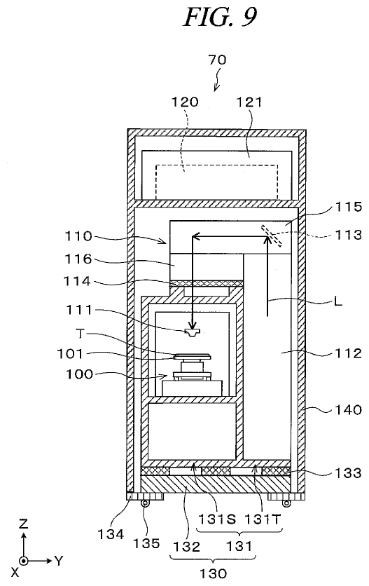

In the wafer processing apparatus 70 of the above-described exemplary embodiment, the mirror box 115 is aligned with the optical system box 116. However, as illustrated in FIG. 8 and FIG. 9, the mirror box 115 may be stacked on top of the laser oscillator 112 above the optical system box 116. For example, when the length (height in the shown example) of the laser oscillator 112 in a longitudinal direction is large, the mirror box 115 is disposed as in the present exemplary embodiment. Even in this case, the width A of the wafer processing apparatus 70 in the X-axis direction can be made smaller than that of the conventional wafer processing apparatus, so that the area occupied by the wafer processing apparatus 70 can be reduced. Further, although the height position of this laser oscillator 112 is slightly higher than that of the laser oscillator 112 in the above-described exemplary embodiment, the height position of this laser oscillator 112 can still be made lower than that of the conventional wafer processing apparatus.

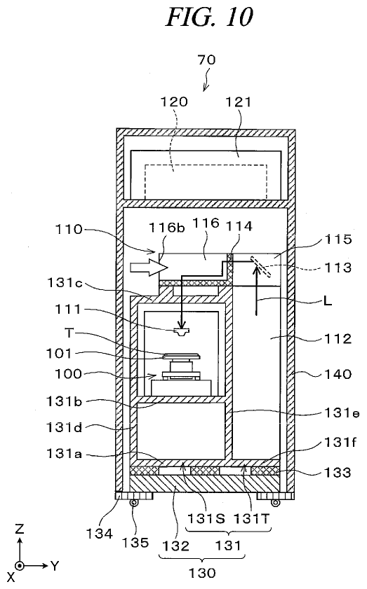

In the wafer processing apparatus 70 according to the above-described exemplary embodiment, the optical system 114 and the optical system box 116 may be configured as shown in FIG. 10. As stated above, the optical system 114 is composed of, for example, a plurality of mirrors, a beam expander, a DOE, and the like. Inside the optical system box 116, these components of the optical system 114 are arranged in a vertical direction on a side surface thereof near the laser oscillator 112 and the mirror box 115, and the mirrors are arranged in a horizontal direction on a bottom surface thereof. The laser light incident from the mirror 113 is emitted downwards through the optical system 114, and is guided to the laser radiation lens 111. A sidewall 116b of the optical system box 116 on the opposite side to the laser oscillator 112 is configured to be detachable. Thus, with the sidewall 116b separated, it is possible to access the inside of the optical system box 116 from a horizontal direction (as indicated by a block arrow of FIG. 10).

In this case, since the inside of the optical system box 116 can be accessed from the horizontal direction and the components of the optical system 114 are arranged in the vertical direction, the accessibility can be improved. As a result, the efficiency of the maintenance of the optical system 114 of the optical system box 116 can be improved.

Further, the optical system box 116 having the detachable sidewall 116b as in the present exemplary embodiment may also be applicable to a configuration in which the mirror box 115 is disposed above the optical system box 116, as illustrated in FIG. 8 and FIG. 9.

The exemplary embodiments disclosed herein are illustrative in all aspects and do not limit the present disclosure. The above-described exemplary embodiments may be omitted, replaced and modified in various ways without departing from the scope and the spirit of the appended claims.

### EXPLANATION OF CODES

1: Wafer processing system
70˜73: Wafer processing apparatus
100: Stage
101: Chuck
111: Laser radiation lens
112: Lase oscillator
113: Mirror
114: Optical system
T: Combined wafer
W: First wafer
S: Second wafer

1. A substrate processing apparatus configured to process a substrate by radiating laser light to the substrate, the substrate processing apparatus comprising:
a substrate holder configured to hold the substrate;
a laser radiation lens configured to radiate the laser light to the substrate held by the substrate holder;
a laser oscillator configured to emit the laser light toward a space above a substrate holding surface of the substrate holder;
a mirror configured to change, above the substrate holder, a direction of the laser light emitted from the laser oscillator into a horizontal direction; and
an optical system configured to adjust an output of the laser light incident from the mirror, and guide the laser light to the laser radiation lens.

2. The substrate processing apparatus of claim 1, further comprising:
a support frame supporting the substrate holder and the laser oscillator.

3. The substrate processing apparatus of claim 2,
wherein the substrate holder and the laser oscillator are arranged in the horizontal direction, and
at least a part of the substrate holder and a part of the laser oscillator are on a level with each other.

4. The substrate processing apparatus of claim 2, further comprising:
a mirror box accommodating the mirror therein; and
an optical system box accommodating the optical system therein.

5. The substrate processing apparatus of claim 4,
wherein the optical system is disposed, inside the optical system box, on a side surface of the optical system box near the laser oscillator, and
the optical system box is configured such that an inside of the optical system box is allowed to be accessed from a side surface of the optical system box opposite to the laser oscillator.

6. The substrate processing apparatus of claim 4,
wherein the support frame supports the mirror box and the optical system box.

7. The substrate processing apparatus of claim 2,
wherein the support frame includes an upper support frame and a lower support frame, and
an insulator is provided between the upper support frame and the lower support frame.

8. The substrate processing apparatus of claim 7, further comprising:
a connection frame provided outside the support frame,
wherein the lower support frame and the connection frame are connected.

9. The substrate processing apparatus of claim 8, further comprising:
an electric equipment box accommodating an electric equipment therein,
wherein the electric equipment box is supported by the connection frame above the substrate holder and the laser oscillator.

10. A substrate processing system, comprising:
a substrate processing apparatus configured to process a substrate by radiating laser light to the substrate; and
a substrate transfer device configured to transfer the substrate to the substrate processing apparatus,
wherein the substrate processing apparatus comprises:
a substrate holder configured to hold the substrate;
a laser radiation lens configured to radiate the laser light to the substrate held by the substrate holder;
a laser oscillator configured to emit the laser light toward a space above a substrate holding surface of the substrate holder;
a mirror configured to change, above the substrate holder, a direction of the laser light emitted from the laser oscillator into a horizontal direction; and
an optical system configured to adjust an output of the laser light incident from the mirror, and guide the laser light to the laser radiation lens.

11. The substrate processing system of claim 10,
wherein the substrate processing apparatus includes multiple substrate processing apparatuses,
the substrate processing system further comprises:
a support frame supporting the substrate holder and the laser oscillator; and
a connection frame provided outside the support frame, and
wherein the connection frame includes multiple connection frames, and the multiple connection frames are arranged in the horizontal direction.

12. The substrate processing system of claim 10, further comprising:
a support frame supporting the substrate holder and the laser oscillator;
a connection frame provided outside the support frame; and
a frame of a substrate transfer region accommodating the substrate transfer device therein,
wherein the connection frame and the frame of the substrate transfer region are arranged in the horizontal direction.

13. The substrate processing system of claim 10,
wherein the substrate transfer device, the substrate holder, and the laser oscillator are arranged in this order in the horizontal direction.

14. The substrate processing system of claim 10,
wherein the substrate processing apparatus includes multiple substrate processing apparatuses, and
the laser oscillator, the substrate holder, the substrate transfer device, the substrate holder, and the laser oscillator are arranged in this order in the horizontal direction.

15. The substrate processing system of claim 13,
wherein at least a part of the substrate holder and a part of the laser oscillator are on a level with each other.

16. A substrate processing method of processing a substrate by radiating laser light to the substrate, the substrate processing method comprising:
holding the substrate with a substrate holder;
emitting laser light from a laser oscillator toward a space above a substrate holding surface of the substrate holder;
changing, above the substrate holder, a direction of the laser light emitted from the laser oscillator into a horizontal direction by using a mirror;
adjusting an output of the laser light incident from the mirror, and guiding the laser light to a laser radiation lens by using an optical system; and
radiating the laser light from the laser radiation lens to the substrate held by the substrate holder.
